(19) United States
(12) Patent Application Publication
(10) Pub. No.: US 2024/0386862 A1
(43) Pub. Date: Nov. 21, 2024

(54) DISPLAY PANEL

(71) Applicant: Guangzhou China Star Optoelectronics Semiconductor Display Technology Co., LTd., Guangzhou (CN)

(72) Inventors: Jing YU, Guangzhou (CN); Juan XIAO, Guangzhou (CN)

(73) Assignee: Guangzhou China Star Optoelectronics Semiconductor Display Technology Co., LTd., Guangzhou (CN)

(21) Appl. No.: 18/509,336

(22) Filed: Nov. 15, 2023

(30) Foreign Application Priority Data
May 17, 2023 (CN) 202310558064.2

(51) Int. Cl. G09G 3/36

(52) U.S. Cl. CPC G09G 3/3677; G09G 2320/0233; G09G 2320/0247

(57) ABSTRACT

Display panels are provided. The display panel includes a display area and a non-display area located at a periphery of the display area; the display panel further includes: a substrate, and a functional element, a first common voltage input line, a second common voltage input line and first connecting lines which are disposed on the substrate; and the functional element is located in the non-display area, the first common voltage input line is located at a side of the functional element facing away from the display area, the second common voltage input line is located at a side of the functional element facing away from the first common voltage input line, and the first connecting lines pass through the functional element and electrically connected between the first common voltage input line and the second common voltage input line.

### CROSS-REFERENCE TO RELATED APPLICATION

This application claims priority to Chinese Patent Application No. 202310558064.2, filed on May 17, 2023, the disclosure of which is incorporated herein by reference in its entirety.

### TECHNICAL FIELD

The present disclosure relates to the field of display technologies, and in particular, to display panels.

### BACKGROUND

With the development of liquid crystal display (LCD) technologies, a demand for large-size display panels is increasing. However, due to a larger size of the large-size display panel, a corresponding load is larger than that of a small-size display panel, which will lead to a signal delay of the display panel. For example, a delay is generated when transmitting common voltage (COM) signals to a far end, which will cause uneven display on the display panel, produce mura (i.e., uneven brightness) and flicker, and affect the display quality.

### SUMMARY

The present disclosure provides display panels to alleviate the technical problem of delay in transmitting common voltage signals to a far end in the existing display panels.

In order to solve the above problem, technical solutions provided by the present disclosure are as follows.

An embodiment of the present disclosure provides a display panel, including: a display area and a non-display area located at a periphery of the display area; and the display panel further includes:
a substrate;
a functional element, disposed on the substrate and located in the non-display area;
a first common voltage input line, disposed on the substrate and located at a side of the functional element facing away from the display area;
a second common voltage input line, disposed on the substrate and located at a side of the functional element facing away from the first common voltage input line;
multiple first connecting lines, passing through the functional element and electrically connected between the first common voltage input line and the second common voltage input line.

In a display panel provided by an embodiment of the present disclosure, the second common voltage input line is located in the non-display area, the second common voltage input line surrounds the display area, and the first common voltage input line semi-surrounds the second common voltage input line.

In a display panel provided by an embodiment of the present disclosure, the non-display area includes an upper frame area, a lower frame area, a left frame area and a right frame area; the upper frame area and the lower frame area are opposite to each other, the left frame area and the right frame area are connected with the upper frame area and the lower frame area, and the left frame area and the right frame area are opposite to each other; and the first common voltage input line extends from the left frame area to the upper frame area and from the upper frame area to the right frame area.

In a display panel provided by an embodiment of the present disclosure, the functional element includes first functional elements and a second functional element, the first functional elements are respectively located in the left frame area and the right frame area, the second functional element is located in the upper frame area, and functions of the first functional elements is different from a function of the second functional element.

In a display panel provided by an embodiment of the present disclosure, the first functional element is a gate on array (GOA) circuit, and the GOA circuit is provided with an avoidance zone at a position corresponding to the first connecting line.

In a display panel provided by an embodiment of the present disclosure, the second functional element is a detection circuit, a gap is defined between the second functional element and the first functional element, and the second common voltage input line is electrically connected with the first common voltage input line through the gap.

In a display panel provided by an embodiment of the present disclosure, the display panel further includes a flexible printed circuit board located in the lower frame area and multiple second connecting lines located in the lower frame area, the first common voltage input line and the second common voltage input line are electrically connected with the flexible printed circuit board, and a part of the second common voltage input line located in the lower frame area is further electrically connected with the flexible printed circuit board through the second connecting lines.

In a display panel provided by an embodiment of the present disclosure, the display area includes a first display area and a second display area adjacent to each other, multiple first common voltage lines are disposed in the first display area, and multiple second common voltage lines are disposed in the second display area, and the first common voltage lines and the second common voltage lines are insulated; and
the first common voltage input line is disconnected at a junction of the first display area and the second display area, the second common voltage input line is disconnected at the junction of the first display area and the second display area; and a part of the first common voltage input line corresponding to the first display area and a part of the second common voltage input line corresponding to the first display area are electrically connected with the first common voltage lines, and a part of the first common voltage input line corresponding to the second display area and a part of the second common voltage input line corresponding to the second display area are electrically connected with the second common voltage lines.

In a display panel provided by an embodiment of the present disclosure, the first display area includes a first sub-display area and a second sub-display area adjacent to each other, and the first common voltage lines include multiple first sub-common voltage lines located in the first sub-display area and multiple second sub-common voltage lines located in the second sub-display area; and the second display area includes a third sub-display area and a fourth sub-display area adjacent to each other, the second common voltage lines include multiple third sub-common voltage lines located in the third sub-display area and multiple fourth sub-common voltage lines located in the fourth sub-display area;

the part of the first common voltage input line corresponding to the first display area is disconnected at a junction of the first sub-display area and the second sub-display area, and the part of the second common voltage input line corresponding to the first display area is disconnected at the junction of the first sub-display area and the second sub-display area; and a part of the first common voltage input line corresponding to the first sub-display area and a part of the second common voltage input line corresponding to the first sub-display area are electrically connected with the first sub-common voltage lines, and a part of the first common voltage input line corresponding to the second sub-display area and a part of the second common voltage input line corresponding to the second sub-display area are electrically connected with the second sub-common voltage lines; and
the part of the first common voltage input line corresponding to the second display area is disconnected at a junction of the third sub-display area and the fourth sub-display area, and the part of the second common voltage input line corresponding to the second display area is disconnected at the junction of the third sub-display area and the fourth sub-display area; and a part of the first common voltage input line corresponding to the third sub-display area and a part of the second common voltage input line corresponding to the third sub-display area are electrically connected with the third sub-common voltage lines, and a part of the first common voltage input line corresponding to the fourth sub-display area and a part of the second common voltage input line corresponding to the fourth sub-display area are electrically connected with the fourth sub-common voltage lines.

In a display panel provided by an embodiment of the present disclosure, a voltage on the part of the first common voltage input line corresponding to the first sub-display area is different from a voltage on the part of the first common voltage input line corresponding to the second sub-display area.

Beneficial effects of the present disclosure are as follows: in a display panel provided by the present disclosure, the display panel includes a display area and a non-display area located at a periphery of the display area, the display panel further includes a substrate, and a functional element, a first common voltage input line, a second common voltage input line and multiple first connecting lines which are disposed on the substrate, the functional element is located in the non-display area, the first common voltage input line is located at a side of the functional element facing away from the display area, the second common voltage input line is located at a side of the functional element facing away from the first common voltage input line, and the first connecting lines pass through the functional element and are electrically connected between the first common voltage input line and the second common voltage input line, so that voltage differences on the second common voltage input line can be reduced, a delay in transmitting common voltage signals to a far end can be avoided, and the technical problem of the delay in transmitting common voltage signals to a far end in the existing display panels can be solved.

### BRIEF DESCRIPTION OF THE DRAWINGS

In order to explain the technical solutions of the embodiments or the related art more clearly, the drawings needed to be used in the description of the embodiments or the related art will be briefly introduced below. Apparently, the drawings described below are only some of the embodiments of the present disclosure. For those skilled in the art, other drawings can be obtained according to these drawings without creative work.

FIG. 1 illustrates a schematic view of a top view structure of a display panel provided by an embodiment of the present disclosure.

FIG. 2 illustrates a schematic view of a cross-sectional structure along a N-N′ direction in FIG. 1.

FIG. 3 illustrates a schematic view of another top view structure of a display panel provided by an embodiment of the present disclosure.

FIG. 4 illustrates a schematic view of still another top view structure of a display panel provided by an embodiment of the present disclosure.

### DETAILED DESCRIPTION

The following description of various embodiments refers to the attached drawings to illustrate specific embodiments that can be practiced in the present disclosure. Directional terms mentioned in the present disclosure, such as [upper], [lower], [front], [rear], [left], [right], [inside], [outside], [side], etc., are only directions referring to the attached drawings. Therefore, the directional terms used are used to illustrate and understand the present disclosure, not to limit the present disclosure. In the drawings, units with similar structures are denoted by the same reference numerals. In the drawings, thicknesses of some layers and areas are exaggerated for clarity of understanding and convenience of description. That is, the size and thickness of each component shown in the drawings are arbitrarily shown, but the present disclosure is not limited to this.

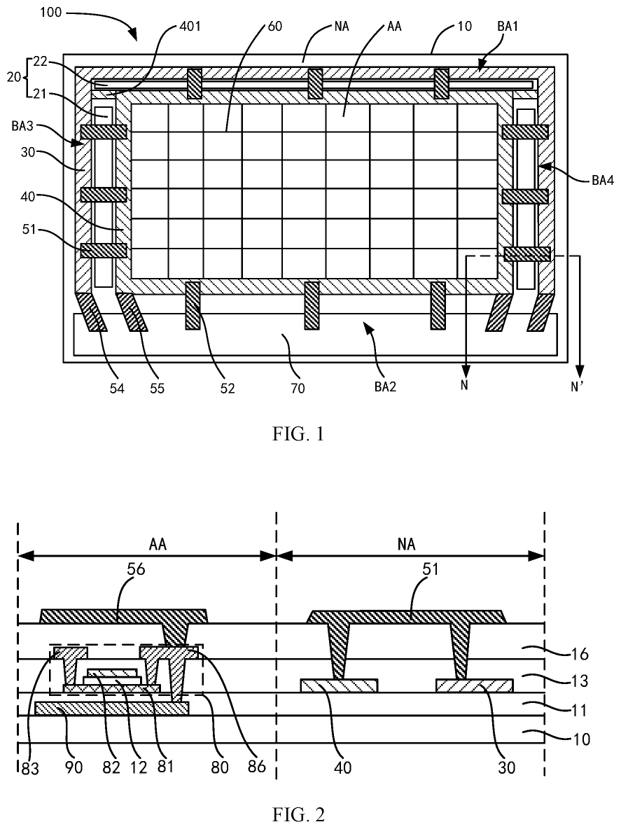

Please refer to FIG. 1 to FIG. 2, FIG. 1 illustrates a schematic view of a top view structure of a display panel provided by an embodiment of the present disclosure, and FIG. 2 illustrates a schematic view of a cross-sectional structure along a N-N′ direction in FIG. 1. A display panel 100 is a LCD panel, an organic light-emitting diode (OLED) display panel, and the like. The display panel 100 includes a display area AA and a non-display area NA located at a periphery of the display area AA. The display panel 100 further includes a substrate 10, a functional element 20 disposed on the substrate 10, a first common voltage input line 30 disposed on the substrate 10, a second common voltage input line 40 disposed on the substrate 10 and multiple first connecting lines 51 disposed on the substrate 10. The functional element 20 is located in the non-display area NA. The first common voltage input line 30 is located at a side of the functional element 20 facing away from the display area AA. The second common voltage input line 40 is located at a side of the functional element 20 facing away from the first common voltage input line 30. The first connecting lines 51 pass through the functional element 20 and are electrically connected between the first common voltage input line 30 and the second common voltage input line 40.

In the present disclosure, the first connecting lines 51 passing through the functional element 20 are provided to electrically connect the first common voltage input line 30 and the second common voltage input line 40, so that voltage differences at different positions on the second common voltage input line 40 can be reduced, a delay in transmitting common voltage signals to a far end can be avoided, and the technical problem of the delay in transmitting common voltage signals to a far end in the existing display panels can be solved.

Specifically, referring to FIG. 1, the display panel 100 includes the display area AA and the non-display area NA. The display area AA is used to display a picture to realize a display function of the display panel 100. The non-display area NA surrounds the display area AA, and the non-display area NA is used to set the functional element 20 and/or signal lines. The non-display area NA includes an upper frame area BA1 and a lower frame area BA2 which are opposite to each other, and a left frame area BA3 and a right frame area BA4 which are connected with the upper frame area BA1 and the lower frame area BA2, and the left frame area BA3 and the right frame area BA4 are disposed opposite to each other.

The functional element 20 is disposed on the substrate 10 and located in the non-display area NA. Optionally, the substrate 10 is a flexible substrate or a rigid substrate, and when the substrate 10 is the flexible substrate, it can be made of polyimide or the like; when the substrate 10 is the rigid substrate, it can be made of glass or the like.

Optionally, the functional element 20 includes first functional elements 21 and a second functional element 22, the first functional elements 21 are respectively located in the left frame area BA3 and the right frame area BA4, and the second functional element 22 is located in the upper frame area BA. A gap is defined between each first functional element 21 and the second functional element 22. Functions of the first functional elements 21 are different from a function of the second functional element 22. For example, each first functional element 21 is a GOA circuit, and the second functional element 22 is a detection circuit. The detection circuit is used to detect whether a signal line in the display panel 100 has a short circuit or an open circuit, or the detection circuit can also be used to detect static electricity in the display panel 100.

The first common voltage input line 30 and the second common voltage input line 40 are both disposed on the substrate 10 and located at two opposite sides of the functional element 20, and the first common voltage input line 30 and the second common voltage input line 40 are located in the non-display area NA. The second common voltage input line 40 surrounds the display area AA, and the first common voltage input line 30 semi-surrounds the second common voltage input line 40.

Specifically, the first common voltage input line 30 extends from the left frame area BA3 to the upper frame area BA1 and from the upper frame area BA1 to the right frame area BA4, so as to form an opening in the lower frame area BA2 and form a semi-enclosure for the second common voltage input line 40. The second common voltage input line 40 extends from the left frame area BA3 to the upper frame area BA1, from the upper frame area BA1 to the right frame area BA4, and then from the right frame area BA4 to the lower frame area BA2 to form a closed ring structure. That is, the second common voltage input line 40 is disposed in the upper frame area BA1, the lower frame area BA2, the left frame area BA3 and the right frame area BA4, and the second common voltage input line 40 is located in each frame area.

Furthermore, the second common voltage input line 40 is electrically connected with the first common voltage input line 30 through the gap between each first functional element 21 and the second functional element 22. Specifically, the second common voltage input line 40 is provided with an extending portion 401, which is disposed in the gap between each first functional element 21 and the second functional element 22 and is electrically connected between the first common voltage input line 30 and the second common voltage input line 40.

The first connecting lines 51 are electrically connected between the first common voltage input line 30 and the second common voltage input line 40, so that the first common voltage input line 30 and the second common voltage input line 40 are electrically connected, and voltage values at various positions on the second common voltage input line 40 are close, and voltage differences on the second common voltage input line 40 can be reduced.

Specifically, multiple first connecting lines 51 are disposed in the left frame area BA3, the upper frame area BA1 and the right frame area BA4, for example, the number of the first connecting lines 51 in each frame area is 2, 3, 4, 5, etc., as shown in FIG. 1, three of the first connecting lines 51 are schematically shown, but the present disclosure is not limited to this. In the present disclosure, the number of the first connecting lines 51 can be determined according to a length of the second common voltage input line 40 in each frame area. When the length of the second common voltage input line 40 is long, more first connecting lines 51 can be provided.

By providing the first connecting lines 51 in each frame area, multiple signal access points can be provided on the second common voltage input line 40 in each frame area, so that voltage values at various positions on the second common voltage input line 40 are close to each other, so as to reduce voltage differences on the second common voltage input line 40. In this way, a delay can be avoided when transmitting common voltage signals to a far end. Moreover, when the second common voltage input line 40 transmits the common voltage signals to the common voltage lines 60 in the display area AA, because the voltage values of the positions on the second common voltage input line 40 are close, the voltage values on the common voltage lines 60 in the display area AA are also close, so that the display uniformity of the display panel 100 can be improved, and the display quality can be prevented from being affected by the uneven display of the display panel 100, such as mura and flicker. The common voltage lines 60 in the display area AA are in a crisscross network structure.

Optionally, the functional element 20 is provided with an avoidance zone at a position corresponding to the first connecting line 51, for example, the first functional element 21 is provided with an avoidance zone at a position corresponding to the first connecting line 51, and the second functional element 22 is also provided with an avoidance zone at a position corresponding to the first connecting line 51. Taking the first functional element 21 as an example, the first functional element 21 is a GOA circuit, and the GOA circuit is provided with an avoidance zone at the position corresponding to the first connecting line 51.

The GOA circuit includes GOA units cascaded in multiple stages, and setting the avoidance zone at the position corresponding to the first connecting line 51 can be realized by the following ways: moving a part of the GOA units close to the upper frame area BA1 and another part of the GOA units close to the lower frame area BA2, so as to leave an avoidance space at the position corresponding to the first connecting line 51. Alternatively, by reducing a height of each stage of GOA unit, an avoidance space is left at the position corresponding to the first connecting trace 51. The height of each stage of GOA unit satisfies the following relationship: a=b/c, where a is the height of each stage of GOA unit, b is a height occupied by the first connecting line 51, and c is the number of stages of GOA units.

Furthermore, in order to increase the number of signal access points on the second common voltage input line 40 in the lower frame area BA2, multiple second connecting lines 52 are disposed in the lower frame area. Specifically, the display panel 100 further includes a flexible printed circuit board (FPC) 70 and the second connecting lines 52 which are located in the lower frame area BA2. Both the first common voltage input line 30 and the second common voltage input line 40 are electrically connected with the FPC 70, for example, the first common voltage input line 30 is electrically connected with the FPC 70 through third connecting lines 54, and the second common voltage input line 40 is electrically connected with the FPC 70 through fourth connecting lines 55.

The second common voltage input line 40 in the lower frame area BA2 is also electrically connected with the FPC 70 through the second connecting lines 52, so as to increase the number of signal access points on the second common voltage input line 40 in the lower frame area BA2, and further make the voltage values at various positions on the second common voltage input line 40 close to each other, so as to reduce the voltage differences on the second common voltage input line 40. In this way, the delay can be avoided when transmitting the common voltage signals to the far end.

It should be noted that the signal access point on the second common voltage input line 40 refers to an access point that provides the common voltage to the second common voltage input line 40. For example, the second common voltage input line 40 is electrically connected with the FPC through the fourth connecting lines 55, then a connection point between the fourth connecting line 55 and the second common voltage input line 40 is a first signal access point on the second common voltage input line 40. For another example, the second common voltage input line 40 is electrically connected with the first common voltage input line 30 through the extending portion 401, and a connection point between the extending portion 401 and the second common voltage input line 40 is a second signal access point on the second common voltage input line 40.

The far end refers to an end of the second common voltage input line 40 facing away from the signal access points on the second common voltage input line 40, for example, in the left frame area BA3, an end facing away from the first signal access point and the second signal access point on the second common voltage input line 40 is the far end, that is, a middle part of the second common voltage input line 40 in the left frame area BA3. The middle part of the second common voltage input line 40 is far away from both the first signal access point and the second signal access point, so that the voltage value on the middle part of the second common voltage input line 40 is smaller than that on parts close to the first signal access point and the second signal access point of the second common voltage input line 40.

However, in the present disclosure, the first connecting lines 51 are disposed between the first signal access point and the second signal access point to increase the signal access points on the second common voltage input line 40, so that the voltage values at various positions on the second common voltage input line 40 are close to each other, so as to reduce the voltage differences on the second common voltage input line 40. In this way, the delay can be avoided when transmitting the common voltage signals to the far end.

Optionally, in order to further reduce the voltage differences on the second common voltage input line 40, the first connecting lines 51 are evenly distributed between the first signal access point and the second signal access point. That is, interval distances among the first connecting lines 51 are the same, and an interval distance between the first connecting line 51 proximate to the first signal access point and the first signal access point is equal to an interval distance between two adjacent first connecting lines 51. An interval distance between the first connecting line 51 proximate to the second signal access point and the second signal access point is equal to the interval distance between two adjacent first connecting lines 51.

It can be understood that the designs of the second common voltage input line 40 and the first connecting lines 51 in the upper frame area BA1 and the right frame area BA4 are the same as those in the left frame area BA3. The design principle and function of the second connecting lines 52 in the lower frame area BA2 are the same as those of the first connecting lines 51, so they are not described here.

How to realize the electrical connection between the second common voltage input line 40 and the first common voltage input line 30 will be described in detail with the first connecting lines 51 as an example.

Referring to FIG. 2, the display panel 100 further includes a thin film transistor (TFT) 80 and a first electrode 56, and the first electrode 56 is electrically connected with the TFT 80. The TFT 80 and the first electrode 56 are both located in the display area AA, the TFT 80 is located on the substrate 10, and the first electrode 56 is located at a side of the TFT 80 facing away from the substrate 10.

Specifically, the TFT 80 includes an active layer 81, a grid 82, a source 83 and a drain 86, which are sequentially stacked. The active layer 81 includes a channel, a source region and a drain region located at two sides of the channel. The grid 82 is disposed corresponding to the channel of the active layer 81, the source 83 is electrically connected with the source region of the active layer 81, and the drain 86 is electrically connected with the drain region of the active layer 81. The first electrode 56 is electrically connected with the source 83 or the drain 86, and the embodiment of the present disclosure takes the electrical connection of the first electrode 56 and the drain 86 as an example.

The first common voltage input line 30 is disposed in the same layer as the grid 82, and the second common voltage input line 40 is also disposed in the same layer as the grid 82. The first connecting lines 51 are disposed in the same layer as the first electrode 56, and the first connecting lines 51 are electrically connected with the first common voltage input line 30 and the second common voltage input line 40.

Optionally, the display panel 100 further includes a light shielding layer 90 located between the TFT 80 and the substrate 10, and the light shielding layer 90 is disposed corresponding to the TFT 80. The light shielding layer 90 is used for shielding light and preventing light from illuminating the TFT 80. The shading layer 90 is made of metal or another material with shading performance.

Furthermore, the display panel 100 further includes multiple insulation layers, such as a buffer layer 11 covering the light shielding layer 90 and the substrate 10, a grid insulation layer 12 disposed between the active layer 81 and the grid 82, an interlayer insulation layer 13 covering the grid 82 and the buffer layer 11, and a planarization layer 16 covering the source 83, and the drain 86 and the interlayer insulation layer 13. The active layer 81, the first common voltage input line 30 and the second common voltage input line 40 are disposed on the buffer layer 11. The grid 82 is disposed on the grid insulation layer 12. The source 83 and the drain 86 are disposed on the interlayer insulation layer 13. The first electrode 56 and the first connecting lines 51 are disposed on the planarization layer 16.

It should be noted that “disposed in the same layer” in the present disclosure means that in the preparation process, at least two different structures are obtained by patterning a film layer formed of the same material, and then the at least two different structures are disposed in the same layer. For example, in the embodiment, the first electrode 56 and the first connecting line 51 are obtained by patterning the same conductive film layer, and then the first electrode 56 and the first connecting line 51 are disposed in the same layer.

In an embodiment, referring to FIGS. 1 to 3, FIG. 3 illustrates a schematic view of another top view structure of a display panel provided by an embodiment of the present disclosure. Different from the above embodiment, in a display panel 101 of this embodiment, the display area AA includes a first display area AA1 and a second display area AA2 which are adjacent to each other. Multiple first common voltage lines 61 are disposed in the first display area AA1, multiple second common voltage lines 62 are disposed in the second display area AA2, and the first common voltage lines 61 and the second common voltage lines 62 are insulated.

The first common voltage input line 30 is disconnected at a junction of the first display area AA1 and the second display area AA2, and the junction of the first display area AA1 and the second display area AA2 is located in a middle area of the display area AA of the display panel 101. The second common voltage input line 40 is disconnected at the junction of the first display area AA1 and the second display area AA2. A part of the first common voltage input line 30 corresponding to the first display area AA1 and a part of the second common voltage input line 40 corresponding to the first display area AA1 are electrically connected with the first common voltage lines 61, and a part of the first common voltage input line 30 corresponding to the second display area AA2 and a part of the second common voltage input line 40 corresponding to the second display area AA2 are electrically connected with the second common voltage lines 62.

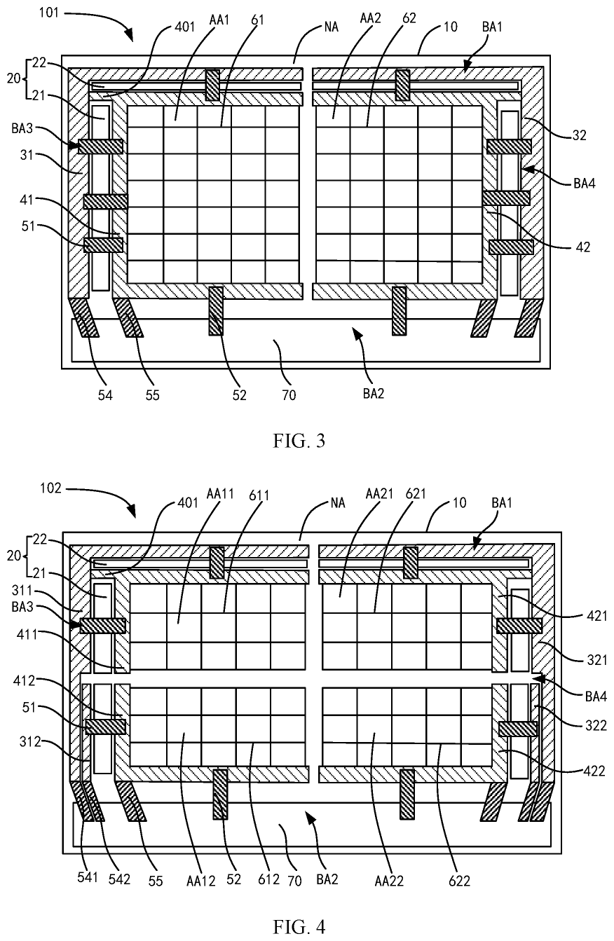

Specifically, referring to FIG. 3, the first common voltage input line 30 is disconnected in the upper frame area BA1, so that the first common voltage input line 30 is divided into a first input line 31 corresponding to the first display area AA1 and a second input line 32 corresponding to the second display area AA2. The second common voltage input line 40 is disconnected in the upper frame area BA1 and the lower frame area BA2, so that the second common voltage input line 40 is divided into a third input line 41 corresponding to the first display area AA1 and a fourth input line 42 corresponding to the second display area AA2. The first input line 31 is electrically connected with the third input line 41 through the corresponding first connecting lines 51, and the second input line 32 is electrically connected with the fourth input line 42 through the corresponding first connecting lines 51. The third input line 41 is electrically connected with the first common voltage lines 61, and the fourth input line 42 is electrically connected with the second common voltage lines 62.

In the embodiment, the display area AA of the display panel 101 is divided, and the first common voltage input line 30 and the second common voltage input line 40 are disconnected at the junction of divided areas, so that different divided areas correspond to the independent first common voltage input line 30 and the independent second common voltage input line 40, which can reduce signal transmission lengths of the first common voltage input line 30 and the second common voltage input line 40, so as to reduce the delay during signal transmission. Moreover, the junction of the divided areas is located in the middle area of the display area AA, so that the lengths of the first common voltage input line 30 and the second common voltage input line 40 corresponding to the divided areas are basically the same, so as to further reduce the delay of signal transmission. For other explanations, please refer to the above-mentioned embodiment, and they will not be repeated here.

In an embodiment, please refer to FIGS. 1 to 4, and FIG. 4 illustrates a schematic view of still another top view structure of a display panel provided by an embodiment of the present disclosure. Different from the above embodiments, in a display panel 102 of this embodiment, the first display area AA1 includes a first sub-display area AA11 and a second sub-display area AA12 which are adjacent to each other, and the first common voltage lines 61 include multiple first sub-common voltage lines 611 located in the first sub-display area AA11 and multiple second sub-common voltage lines 612 located in the second sub-display area AA12. The second display area AA2 includes a third sub-display area AA21 and a fourth sub-display area AA22 which are adjacent to each other, and the second common voltage lines 62 include multiple third sub-common voltage lines 621 located in the third sub-display area AA21 and multiple fourth sub-common voltage lines 622 located in the fourth sub-display area AA22.

The part of the first common voltage input line 30 corresponding to the first display area AA1 is disconnected at a junction of the first sub-display area AA11 and the second sub-display area AA12, and the part of the second common voltage input line 40 corresponding to the first display area AA1 is disconnected at the junction of the first sub-display area AA11 and the second sub-display area AA12. A part of the first common voltage input line 30 corresponding to the first sub-display area AA11 and a part of the second common voltage input line 40 corresponding to the first sub-display area AA11 are electrically connected with the first sub-common voltage lines 611, and a part of the first common voltage input line 30 corresponding to the second sub-display area AA12 and a part of the second common voltage input line 40 corresponding to the second sub-display area AA12 are electrically connected with the second sub-common voltage lines 612.

The part of the first common voltage input line 30 corresponding to the second display area AA2 is disconnected at a junction of the third sub-display area AA21 and the fourth sub-display area AA22, and the part of the second common voltage input line 40 corresponding to the second display area AA2 is disconnected at the junction of the third sub-display area AA21 and the fourth sub-display area AA22. A part of the first common voltage input line 30 corresponding to the third sub-display area AA21 and a part of the second common voltage input line 40 corresponding to the third sub-display area AA21 are electrically connected with the third sub-common voltage lines 621, and a part of the first common voltage input line 30 corresponding to the fourth sub-display area AA22 and a part of the second common voltage input line 40 corresponding to the fourth sub-display area AA22 are electrically connected with the fourth sub-common voltage lines 622.

Specifically, referring to FIGS. 3 and 4, the first input line 31 is disconnected at the junction of the first sub-display area AA11 and the second sub-display area AA12, so that the first input line 31 is divided into a first sub-input line 311 corresponding to the first sub-display area AA1l and a second sub-input line 312 corresponding to the second sub-display area AA12. The second input line 32 is disconnected at the junction of the third sub-display area AA21 and the fourth sub-display area AA22, so that the second input line 32 is divided into a third sub-input line 321 corresponding to the third sub-display area AA21 and a fourth sub-input line 322 corresponding to the fourth sub-display area AA22.

The third input line 41 is disconnected at the junction of the first sub-display area AA11 and the second sub-display area AA12, so that the third input line 41 is divided into a fifth sub-input line 411 corresponding to the first sub-display area AA11 and a sixth sub-input line 412 corresponding to the second sub-display area AA12. The fifth sub-input line 411 is electrically connected with the first sub-input line 311 through the corresponding first connecting lines 51, and the fifth sub-input line 411 is further electrically connected with the first sub-common voltage lines 611. The sixth sub-input line 412 is electrically connected with the second sub-input line 312 through the corresponding first connecting lines 51, and the sixth sub-input line 412 is further electrically connected with the second sub-common voltage lines 612.

The fourth input line 42 is disconnected at the junction of the third sub-display area AA21 and the fourth sub-display area AA22, so that the fourth input line 42 is divided into a seventh sub-input line 421 corresponding to the third sub-display area AA21 and an eighth sub-input line 422 corresponding to the fourth sub-display area AA22. The seventh sub-input line 421 is electrically connected with the third sub-input line 321 through the corresponding first connecting lines 51, and the seventh sub-input line 421 is further electrically connected with the third sub-common voltage lines 621. The eighth sub-input line 422 is electrically connected with the fourth sub-input line 322 through the corresponding first connecting lines 51, and the eighth sub-input line 422 is further electrically connected with the fourth sub-common voltage lines 622.

Accordingly, each third connecting line 54 is divided into a first sub-connecting line 541 and a second sub-connecting line 542. The first sub-input line 311 and the third sub-input line 321 are connected with the FPC 70 through the corresponding first sub-connecting lines 541. The second sub-input line 312 and the fourth sub-input line 322 are connected with the FPC 70 through the corresponding second sub-connecting lines 542.

By further dividing the display area AA of the display panel 102, the signal transmission lengths of the first common voltage input line 30 and the second common voltage input line 40 is further reduced, so as to reduce the delay in signal transmission. Moreover, the junction of the divided areas is located in the middle area of the display area AA, so that the lengths of the first common voltage input line 30 and the second common voltage input line 40 corresponding to the divided areas are basically the same, so as to further reduce the delay of signal transmission.

Furthermore, a voltage on the part of the first common voltage input line 30 corresponding to the first sub-display area AA11 is different from a voltage on the part of the first common voltage input line 30 corresponding to the second sub-display area AA12, so that voltages on the first sub-common voltage lines 611 in the first sub-display area AA11 are close to voltages on the second sub-common voltage lines 612 in the second sub-display area AA12, so as to improve the display uniformity of the first sub-display area AA11 and the second sub-display area AA12.

Accordingly, a voltage on the part of the first common voltage input line 30 corresponding to the third sub-display area AA21 is different from a voltage on the part of the first common voltage input line 30 corresponding to the fourth sub-display area AA22, so that voltages on the third sub-common voltage lines 621 in the third sub-display area AA21 are close to voltages on the fourth sub-common voltage lines 622 in the fourth sub-display area AA22, so as to improve the display uniformity of the third sub-display area AA21 and the fourth sub-display area AA22, and thereby to improve the display uniformity of the entire display area AA.

In order to accurately determine the voltage on the part of the first common voltage input line 30 corresponding to the first sub-display area AA11 and the voltage on the part of the first common voltage input line 30 corresponding to the second sub-display area AA12, the display panel 102 may further include a detection circuit for detecting the voltage on the part of the first common voltage input line 30 corresponding to each divided area and compensating the voltage on the part of the first common voltage input line 30 corresponding to the corresponding divided area according to the detection result. A distance between the first sub-display area AA11 and the FPC 70 is greater than a distance between the second sub-display area AA12 and the FPC 70, so that the transmission length of the part of the first common voltage input line 30 corresponding to the first sub-display area AA11 is longer. The voltage value on the part of the first common voltage input line 30 corresponding to the first sub-display area AA11 can be made larger than that on the part of the first common voltage input line 30 corresponding to the second sub-display area AA12, and the voltage value on the part of the first common voltage input line 30 corresponding to the first sub-display area AA11 can be compensated in real time according to the detection result of the detection circuit. Such that the voltages transmitted from the part of the first common voltage input line 30 corresponding to the first sub-display area AA11 to the first sub-common voltage lines 611 are the same as the voltages transmitted from the part of the first common voltage input line 30 corresponding to the second sub-display area AA12 to the second sub-common voltage lines 612, thereby further improving the display uniformity. For other explanations, please refer to the above-mentioned embodiments, and they will not be repeated here.

As can be seen from the above embodiments:

The present disclosure provides a display panel, which includes a display area and a non-display area located at a periphery of the display area. The display panel further includes a substrate, and a functional element, a first common voltage input line, a second common voltage input line and connecting lines which are disposed on the substrate, the functional element is located in the non-display area, the first common voltage input line is located at a side of the functional element facing away from the display area, the second common voltage input line is located at a side of the functional element facing away from the first common voltage input line, and the first connecting lines pass through the functional element and are electrically connected between the first common voltage input line and the second common voltage input line, so that voltage differences on the second common voltage input line can be reduced, a delay in transmitting common voltage signals to a far end can be avoided, and the technical problem of the delay in transmitting common voltage signals to a far end in the existing display panels can be solved.

In the above-mentioned embodiments, the description of each embodiment has its own emphasis. For the parts not detailed in one embodiment, please refer to the relevant descriptions of other embodiments.

The above provides a detailed introduction to the embodiments of the present disclosure. Specific examples are applied in this paper to explain the principles and implementation methods of the present disclosure. The explanations of the above embodiments are only used to help understand the technical solutions and core ideas of the present disclosure. Those skilled in the art should understand that they can still amend the technical solutions recorded in the above-mentioned embodiments, or replace some technical features with equivalents. However, these amendments or substitutions do not separate the essence of the corresponding technical solutions from the scope of the technical solutions of the various embodiments of the present disclosure.

What is claimed is:

1. A display panel, comprising: a display area and a non-display area located at a periphery of the display area; wherein the display panel further comprises:
a substrate;
a functional element, disposed on the substrate and located in the non-display area;
a first common voltage input line, disposed on the substrate and located at a side of the functional element facing away from the display area;
a second common voltage input line, disposed on the substrate and located at a side of the functional element facing away from the first common voltage input line; and
a plurality of first connecting lines, passing through the functional element and electrically connected between the first common voltage input line and the second common voltage input line.

2. The display panel of claim 1, wherein the second common voltage input line is located in the non-display area, the second common voltage input line surrounds the display area, and the first common voltage input line semi-surrounds the second common voltage input line.

3. The display panel of claim 2, wherein the non-display area comprises an upper frame area, a lower frame area, a left frame area and a right frame area; the upper frame area and the lower frame area are opposite to each other, the left frame area and the right frame area are connected with the upper frame area and the lower frame area, and the left frame area and the right frame area are opposite to each other; and the first common voltage input line extends from the left frame area to the upper frame area and from the upper frame area to the right frame area.

4. The display panel of claim 3, wherein the functional element comprises first functional elements and a second functional element, the first functional elements are respectively located in the left frame area and the right frame area, the second functional element is located in the upper frame area, and functions of the first functional elements is different from a function of the second functional element.

5. The display panel of claim 4, wherein each of the first functional elements is a gate on array (GOA) circuit, and the GOA circuit is provided with an avoidance zone at a position corresponding to each of the plurality of first connecting lines.

6. The display panel of claim 4, wherein the second functional element is a detection circuit, a gap is defined between the second functional element and each of the first functional elements, and the second common voltage input line is electrically connected with the first common voltage input line through the gap.

7. The display panel of claim 3, wherein the display panel further comprises a flexible printed circuit board located in the lower frame area and a plurality of second connecting lines located in the lower frame area, the first common voltage input line and the second common voltage input line are electrically connected with the flexible printed circuit board, and a part of the second common voltage input line located in the lower frame area is further electrically connected with the flexible printed circuit board through the plurality of second connecting lines.

8. The display panel according to claim 1, wherein the display area comprises a first display area and a second display area adjacent to each other, a plurality of first common voltage lines are disposed in the first display area, and a plurality of second common voltage lines are disposed in the second display area, and the plurality of first common voltage lines and the plurality of second common voltage lines are insulated; and
wherein the first common voltage input line is disconnected at a junction of the first display area and the second display area, the second common voltage input line is disconnected at the junction of the first display area and the second display area; and a part of the first common voltage input line corresponding to the first display area and a part of the second common voltage input line corresponding to the first display area are electrically connected with the plurality of first common voltage lines, and a part of the first common voltage input line corresponding to the second display area and a part of the second common voltage input line corresponding to the second display area are electrically connected with the plurality of second common voltage lines.

9. The display panel of claim 8, wherein the first display area comprises a first sub-display area and a second sub-display area adjacent to each other, and the plurality of first common voltage lines comprise a plurality of first sub-common voltage lines located in the first sub-display area and a plurality of second sub-common voltage lines located in the second sub-display area; and the second display area comprises a third sub-display area and a fourth sub-display area adjacent to each other, the plurality of second common voltage lines comprise a plurality of third sub-common voltage lines located in the third sub-display area and a plurality of fourth sub-common voltage lines located in the fourth sub-display area;
wherein the part of the first common voltage input line corresponding to the first display area is disconnected at a junction of the first sub-display area and the second sub-display area, and the part of the second common voltage input line corresponding to the first display area is disconnected at the junction of the first sub-display area and the second sub-display area; and a part of the first common voltage input line corresponding to the first sub-display area and a part of the second common voltage input line corresponding to the first sub-display area are electrically connected with the plurality of first sub-common voltage lines, and a part of the first common voltage input line corresponding to the second sub-display area and a part of the second common voltage input line corresponding to the second sub-display area are electrically connected with the plurality of second sub-common voltage lines; and
wherein the part of the first common voltage input line corresponding to the second display area is disconnected at a junction of the third sub-display area and the fourth sub-display area, and the part of the second common voltage input line corresponding to the second display area is disconnected at the junction of the third sub-display area and the fourth sub-display area; and a part of the first common voltage input line corresponding to the third sub-display area and a part of the second common voltage input line corresponding to the third sub-display area are electrically connected with the plurality of third sub-common voltage lines, and a part of the first common voltage input line corresponding to the fourth sub-display area and a part of the second common voltage input line corresponding to the fourth sub-display area are electrically connected with the plurality of fourth sub-common voltage lines.

10. The display panel of claim 9, wherein a voltage on the part of the first common voltage input line corresponding to the first sub-display area is different from a voltage on the part of the first common voltage input line corresponding to the second sub-display area.
